(19) United States
(12) Patent Application Publication
(10) Pub. No.: US 2024/0411964 A1
(43) Pub. Date: Dec. 12, 2024

(54) LONG-TERM SCHEDULING METHOD FOR INDUSTRIAL BYPRODUCT GAS SYSTEM

(71) Applicant: DALIAN UNIVERSITY OF TECHNOLOGY, Dalian, Liaoning (CN)

(72) Inventors: Tianyu WANG, Dalian, Liaoning (CN); Jun ZHAO, Dalian, Liaoning (CN); Wei WANG, Dalian, Liaoning (CN)

(21) Appl. No.: 18/699,786

(22) PCT Filed: Oct. 26, 2021
(86) PCT No.: PCT/CN2021/126242

§ 371 Date: Apr. 9, 2024

(51) Int. Cl. G06F 30/27

(52) U.S. Cl. CPC G06F 30/27

(57) ABSTRACT

A long-term scheduling method for an industrial byproduct gas system comprises the following steps: dividing information granularity according to the fluctuation features of energy data to form semantic representation of a data sample; with granular data features as input, constructing a deep contrastive network structure through expert scheduling experience data, and constructing knowledge representation under different scheduling states in modes of qualitative and quantitative learning; establishing a fully connected output layer to fit expert scheduling amount, to obtain an initial scheduling policy based on experience knowledge; constructing an actor-critic architecture to calculate a compensation policy that considers long-term scheduling performance.

### TECHNICAL FIELD

The present invention belongs to the technical field of information, relates to the technologies of knowledge automation, data-driven modeling and reinforcement learning, and is a long-term scheduling method for an industrial byproduct energy system, which integrates knowledge, data and dynamic programming. Firstly, knowledge representation of an energy system scheduling state is obtained through a granular mode and deep contrastive learning, and an initial scheduling policy is calculated. On this basis, combined with the dynamic programming process of an actor-critic architecture, policy compensation which considers long-term scheduling performance is realized. The method can satisfy the needs for long-term tank level control, energy prediction and balanced dispatching in an industrial site, and the calculation efficiency conforms to the requirements for practical application, which can help to save scheduling cost and achieve energy conservation and emission reduction of a by-product gas system.

### BACKGROUND

Industrial production is a production process with high energy consumption and high emission. With the shortage of primary energy such as coal and oil, full use of secondary energy generated in the production process not only can improve the energy saving and consumption reduction level of enterprises, but also can reduce environmental pollution caused by gas emission. (Jin Feng. Optimized scheduling method and application of steel gas based on causal model [D]. (2020). Dalian University of Technology). Byproduct gas is an important secondary energy produced in the industrial production process, and has the characteristics of large single recovery and large impact on the balance of energy pipe network in a recovery stage. In case of equipment maintenance, equipment failure, production plan change and other situations, supply and demand imbalance may also occur in pipe networks. To better use byproduct resources, field schedulers need to adjust the load of adjustable users according to the current operation state of a gas system and a production plan to ensure the balanced operation of the system.

With the gradual improvement of the industrial informatization level, large enterprises have accumulated a large amount of relevant historical data to provide technical support for optimized energy scheduling. The existing research mainly includes: modeling and reasoning based on Bayesian network (J. Zhao, W. Wang, K. Sun, et al. (2014). A bayesian networks structure learning and reasoning-based byproduct gas scheduling in steel industry [J]. IEEE Transactions on Automation Science and Engineering, 11(4): 1149-1154), two-stage method for predicting modeling and optimized scheduling (Z. Han, J. Zhao, W. Wang, & Y. Liu. (2016). A two-stage method for predicting and scheduling energy in an oxygen/nitrogen system of the steel industry[J]. Control Engineering Practice, 52, 35-45) and causal modeling (F. Jin, J. Zhao, Y. Liu, et al. (2021). A scheduling approach with uncertainties in generation and consumption for converter gas system in steel industry[J]. Information Sciences, 2021, 546:312-328). The above research makes calculation for the single energy imbalance in a short time, and does not comprehensively consider the influence of dynamic characteristics of the production environment, such as equipment operation changes and production plan adjustment, on the scheduling policy in the future time. The multi-time scale scheduling problem of the industrial energy system mainly includes the heuristic optimization method (R. Hemmati, H. Saboori, P. Siano. (2017). Coordinated short-term scheduling and long-term expansion planning in microgrids incorporating renewable energy resources and energy storage systems[J]. Energy, 134:699-708.) and the mix integer programming optimization method (A. Bischi, L. Taccari, E. Martelli, et al. (2019). A rolling-horizon optimization algorithm for the long term operational scheduling of cogeneration systems[J]. Energy, 184:73-90.). However, most of the above literature adopts a static optimization mode. When there is a long-term scheduling problem with multi-stage or multi-step policies, it is difficult to prevent an optimization model from easily falling into local optimum, which will affect long-term indicators including equipment operation and scheduling economy.

### SUMMARY

For an event-triggered industrial byproduct gas system scheduling process, the present invention firstly divides the information granularity according to the fluctuation features of the production process data, and establishes a granular contrastive network by using an expert scheduling sample to realize knowledge representation of the system operation state in the scheduling process and fit the expert scheduling amount in a mode of supervised learning to obtain an initial scheduling policy. Considering the influence of multi-step scheduling events and taking knowledge representation as a state of reinforcement learning, a policy evaluation and dynamic compensation mechanism is established based on an actor-critic architecture, so as to improve the long-term scheduling performance of an energy system. The present invention is beneficial to reduce the scheduling cost and can ensure that an energy storage level is operated in a safety zone for a long time, thereby providing decision support for the scheduling operation of field personnel.

The technical solution of the present invention is as follows:

A long-term scheduling method for an industrial byproduct gas system comprises the following steps:
(1) Dividing information granularity according to the fluctuation features of energy data to form semantic representation of a data sample.
(2) With granular data features as input, constructing a deep contrastive network structure through expert scheduling experience data, and constructing knowledge representation under different scheduling states in modes of qualitative and quantitative learning; and on this basis, establishing a fully connected output layer to fit expert scheduling amount, to obtain an initial scheduling policy based on experience knowledge.

(3) constructing an actor-critic architecture to calculate a compensation policy that considers long-term scheduling performance, wherein a critic part takes the knowledge representation obtained by a contrastive network as a state space to establish a critic value function which takes a scheduling event as a unit, and realizes policy evaluation in a mode of deep Q learning; and an actor part compares the current policy evaluation with an expected target value, calculates the compensation policy based on a target return amount, and obtains a final byproduct energy scheduling solution.

The present invention has the following beneficial effects: the method proposed in the present invention combines knowledge extraction, data-driven modeling and dynamic programming processes. Knowledge acquisition and representation of an energy system scheduling state are realized through a data granular process and the deep contrastive network: the actor-critic architecture which is further constructed can reflect the dynamic change of a production environment and the influence of future multi-step scheduling events, so as to satisfy the needs for long-term tank level operating control, energy prediction and balanced scheduling in an industrial site.

### DESCRIPTION OF DRAWINGS

FIG. 1 is an application flow chart of the present invention.

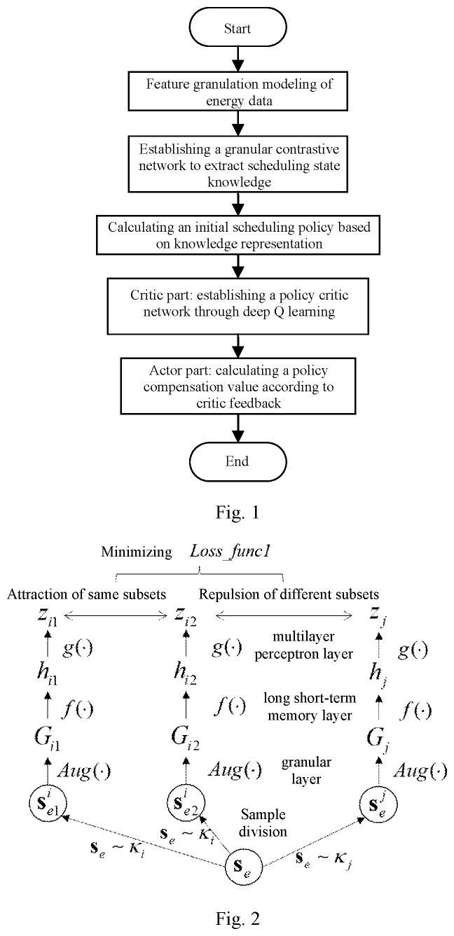

FIG. 2 is a structural diagram of a granular contrastive network.

FIG. 3 describes a multi-level training mechanism of a contrastive network.

FIG. 4 is a structural diagram of a critic network.

FIG. 5 is comparison of tank level scheduling effects for 300 minutes (gas surplus). (a)-(d) respectively represent four gas tanks.

FIG. 6 is comparison of tank level scheduling effects for 300 minutes (gas shortage). (a)-(d) respectively represent four gas tanks.

### DETAILED DESCRIPTION

An industrial byproduct energy system has many variables of occurrence, storage and consumption, and the variables are coupled and associated with each other through an energy transmission network. Meanwhile, the states of energy users are changed with time. These objective factors lead to the operation features of complex and dynamic changes in the energy system. To improve the long-term scheduling performance, a reasonable scheduling policy should be formulated according to different system state characteristics, and the influence of energy system state change and multi-step scheduling events should be considered comprehensively in a mode of dynamic programming. To better understand the technical route and the implementation solution of the present invention, energy scheduling of a converter gas system in a metallurgical enterprise is taken as a research object. Specific implementation steps are described as follows:

### (1) Feature Granulation Modeling of Energy Data

The present invention adopts an adaptive granulation (AG) method to divide data granularity according to the fluctuation tendency characteristics of data. A time series X={x₁, x₂, . . . , xₙ} is given, and first-order and second-order dynamic variables can be represented as

$$Δ = \{ {Δ}_{1} , {Δ}_{2} , … , {Δ}_{n - 1} \} , E = \{ {e}_{1} , {e}_{2} , … , {e}_{n - 2} \} \qquad ( 1 )$$

where Δᵢ=xᵢ₊₁−xᵢ and eᵢ=Δᵢ₊₁−Δᵢ. The concavity and convexity, and monotonicity changes of a sequence segment where a data point xᵢ is located are judged by the symbols of Δᵢ×Δᵢ₋₁ and eᵢ×eᵢ₋₁, and time series data are divided at the time when properties are changed. For example, for a time series X={x₁, x₂, . . . , xₚ, xₚ₊₁, . . . , xₙ} if Δₚ×Δₚ₋₁<0∪eₚ×eₚ₋₁<0, xₚ is used as a segmentation point to divide X into {x₁, x₂, . . . , xₚ} and {xₚ₊₁, xₚ₊₂, . . . , xₙ}. Before granularity division is implemented, the data need to be filtered and preprocessed to eliminate some small trend changes. To further realize semantic enhancement of the data, a three-dimensional feature vector composed of a time span D_{τ}, a fluctuation amplitude A_{τ} and a tendency linetype L_{τ} is used to describe an information grain G_{τ}, recorded as G_{τ}={D_{τ}, A_{τ}, L_{τ}}, where τ is a granularity time step.

### (2) Knowledge Extraction and Policy Calculation Based on a Granular Contrastive Network

A granular contrastive network is established to obtain knowledge representation related to a scheduling state, and an expert adjustment amount in a historical scheduling sample is fitted based on the representation to calculate an initial scheduling policy.

The input of a contrastive network model is granular description of energy occurrence and consumption and storage flow data, i.e., sₑ={G_{τ}⁽¹⁾, G_{τ}⁽²⁾, . . . , G_{τ}⁽ⁿ⁾}, where e represents different scheduling events and n represents the number of input factors. The network structure is shown in

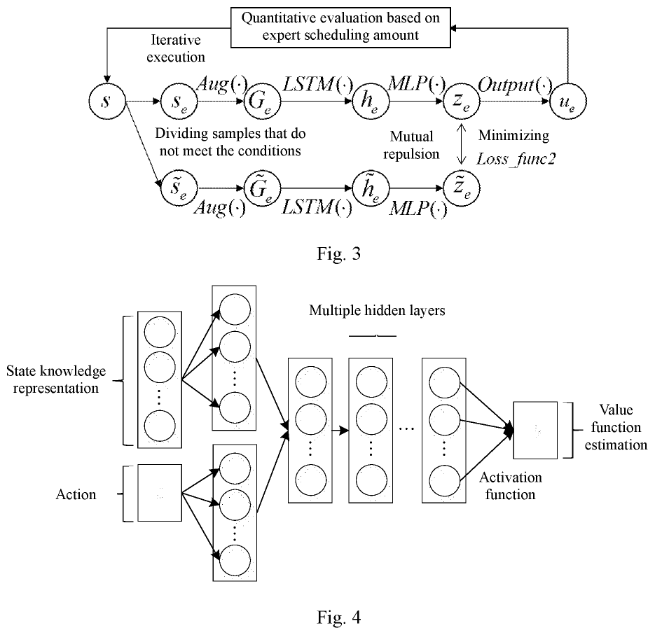

FIG. 2, and can be divided into the following four parts:
1) Firstly, data samples are qualitatively divided into different subsets {sₑ₁ⁱ, sₑ₂ⁱ, . . . }, {sₑ₁^{j}, sₑ₂^{j}, . . . }, . . . , {sₑ₁^{m}, sₑ₂^{m}, . . . } according to the expert scheduling data at historical time (adjusting direction, adjusting amount and the like).
2) An encoder f(⋅) based on a neural network is used to extract a representation vector from granular feature description of the data. The present invention adopts a long short-term memory network to obtain the feature representation of the scheduling state, i.e., hₑ=f(sₑ)=LSTM(sₑ), where hₑ∈ [symbol] ^{d} is the hidden representation of the network.
3) A neural network mapping layer g(⋅) with a single hidden layer is used to map the extracted representation vector to a contrastive loss space, and zₑ obtained by the feature mapping layer has better contrastive learning effect than hₑ of a previous layer. Here, MLP is used to obtain final state knowledge representation, i.e., zₑ=g(hₑ)=MLP(hₑ). After contrastive learning, zₑ can reflect the scheduling state of the energy system compared with sₑ, so zₑ is also used for state space representation in the actor-critic architecture.
4) The fully connected output layer is established based on a knowledge representation vector zₑ to obtain the initial scheduling policy, i.e., uₑ=Output(zₑ).

For the learning process of the established contrastive network, the present invention conducts training from qualitative and quantitative levels respectively:
1) By minimizing a defined loss function, representation vectors {zₑⁱ, zₑ^{j}} of samples {sₑⁱ, sₑ^{j}} qualitatively divided into the same subset by expert scheduling data are close to each other to differentiate representations {zₑⁱ, zₑ^{k}} of different subset samples {sₑⁱ, sₑ^{k}}, so as to distinguish different scheduling conditions as much as possible. The loss function in this process is defined as follows.

$$loss\_func1 = - {\sum }_{i} log ( \frac{{\sum }_{j = 1}^{p} {e}^{d ( {z}_{e}^{i} , {z}_{e}^{j} )}}{{\sum }_{j = 1}^{p} {e}^{d ( {z}_{e}^{i} , {z}_{e}^{j} )} + {\sum }_{k = 1}^{q} {e}^{d ( {z}_{e}^{i} , {z}_{e}^{j} )}} ) \qquad ( 2 )$$

where p represents the number of samples belonging to the same subset as zₑⁱ; q represents the number of samples of different subsets; and d(⋅) represents a distance between the vectors, which is measured by cosine similarity.

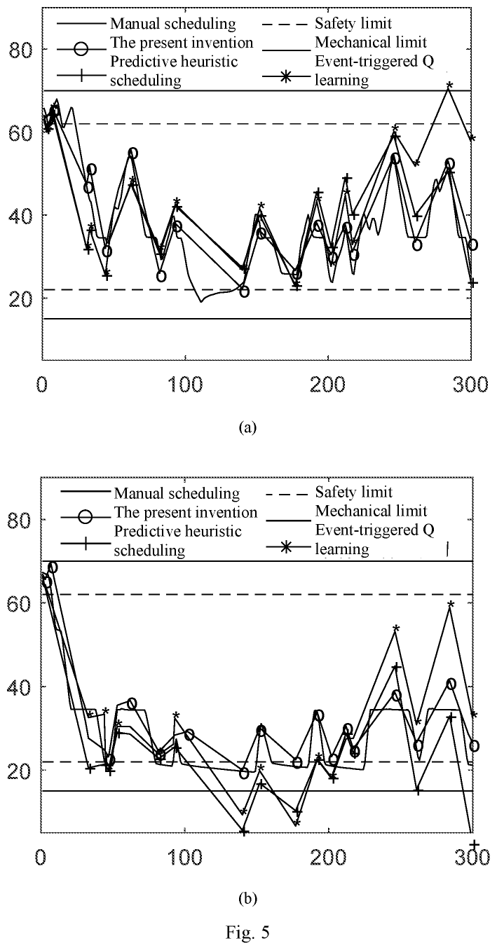

For multi-category situations contained in the expert scheduling data, the present invention proposes a multi-step training policy. In the process of training, firstly, dichotomous contrastive learning is conducted according to a direction of adjustment, and then, input samples with different adjustment amounts are constructed to conduct repeated learning, so that output representation vectors can distinguish multi-category expert knowledge. If the total number of expert experience samples is N and all possible data pairs are used in the training model, the amount of data information used for training can reach (N)(N−1)/2. Compared with a classical supervised learning method, the training process of the contrastive learning model has approximately (N−1)/2 extra samples, so the relatively sparse event-triggered scheduling process data can be used more efficiently.
2) After the above training process is ended, a multi-level training mechanism is further proposed to realize the quantitative learning and detailed representation of scheduling knowledge, as shown in FIG. 3.

Firstly, a validation set {s₁, s₂, . . . , sₗ} is defined, and the corresponding knowledge representation {z₁, z₂, . . . zₗ} is calculated according to the network model obtained from the above process. On the basis of the knowledge representation vectors, an output layer is established to fit expert scheduling amount. An error between calculated scheduling amount and real scheduling amount is used to judge whether the current obtained knowledge representation can satisfy actual system conditions. If the error of a sample data set {\tilde{s}₁, \tilde{s}₂, . . . , \tilde{s}ᵣ} is higher than a set threshold θ, i.e.

$$\vert {y}_{e} - Output ( g ( f ( {\tilde{s}}_{e} ) ) ) \vert > θ , e ∈ [ 1 , r ] \qquad ( 3 )$$

where yₑ is the real scheduling amount. It indicates that the current representation space cannot cover the scheduling knowledge contained in the sample set. In this case, it is necessary to further train the contrastive network model to distinguish {\tilde{s}₁, \tilde{s}₂, . . . , \tilde{s}ᵣ} from other samples in the validation set. Because characteristics different from the existing representation space need to be learned, mutually exclusive loss functions are defined in this process.

$$loss\_func2 = - log ( \frac{1}{{\sum }_{i = 1}^{r} {\sum }_{j = 1}^{l - r} {e}^{d ( {\tilde{z}}_{e}^{i} , {z}_{e}^{j} )}} ) \qquad ( 4 )$$

where r is the number of samples that do not meet the conditions, and l is the total number of samples in the validation set. After the above training is ended, it is necessary to judge whether the samples in the validation set can meet the threshold conditions according to the learned network model again, and perform the above process continuously to realize multi-level iterative learning until all the samples meet the set conditions.

After training of the contrastive learning is ended, granular sample input sₑ is given to obtain the corresponding scheduling state knowledge representation zₑ. The fully connected output layer is established based on the representation; the expert scheduling amount is fitted in a mode of supervised learning; and the initial scheduling policy based on expert knowledge is calculated.

### (3) Calculation of Compensation Policy Based on the Actor-Critic Architecture

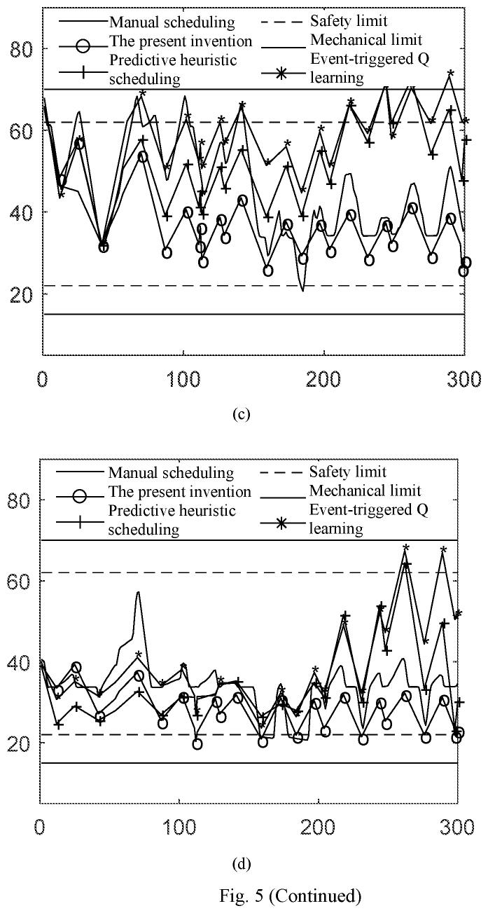

For the long-term scheduling performance of the byproduct energy system, the present invention proposes an actor-critic architecture to realize dynamic compensation for the initial scheduling policy, wherein the critic part uses the knowledge representation zₑ as the state of reinforcement learning to establish a deep Q network for calculating the value function evaluation of the scheduling policy; the actor part uses the initial scheduling policy calculated by the granular contrastive network as the initial solution, and obtains the compensation amount of the scheduling policy in a mode of data fitting according to a deviation between the critic value of the policy and a target setting value, so as to obtain a final scheduling solution.
1) The critic part constructs a critic network to evaluate the scheduling policy. The input of the network is a set of state knowledge representation zₑ and actor (scheduling amount) aₑ which are spliced through a layer of neural network respectively. On this basis, multiple hidden layers and ReLU activation function layers are constructed to establish a deep neural network. The output of the network is a value function Q, and the critic network structure is shown in FIG. 4.

The present invention calculates a scheduling reward at a moment when each scheduling event occurs, so a value function with the scheduling event as a unit is defined, i.e.,

$$Q = {reward}_{1} + γ {reward}_{2} + … + {γ}^{v - 1} {reward}_{v} = {\sum }_{e = 0}^{v - 1} {γ}^{e} {reward}_{e} \qquad ( 5 )$$

Where rewardₖ is defined as the reward of the k^{th} scheduling event, which is described by the critic indicator of the scheduling effect of the byproduct gas system, and defined as

$$reward = \frac{\begin{matrix}prof - loss ▯ ( len - {\sum }_{i = 1}^{len} G ( sign ( ( {t\_level}_{i} + θ - \\ HMB ) ( LMB - θ - {t\_level}_{i} ) ) ) )\end{matrix}}{1 + len - {\sum }_{i = 1}^{len} G ( sign ( ( {t\_level}_{i} - LSB ) ( HSB - {t\_level}_{i} ) ) )} \qquad ( 6 )$$

where prof is a fixed profit at this stage; loss is a profit lost each time that a tank level reaches a mechanical upper (lower) limit; the content in parentheses after the loss represents the number of times that the tank level reaches the mechanical upper (lower) limit; len is the duration of the scheduling event; θ is a threshold with a smaller value; t_levelᵢ is a tank level value at the i^{th} moment; HMB, LMB, HSB and LSB represent the mechanical upper and lower limits and safety upper and lower limits of the tank level respectively, and sign(▪) and G(▪) functions are respectively shown in formula (7).

$$sign ( x ) = \{ \begin{matrix}1 & x > 0 \\ 0 & x = 0 \\ - 1 & x < 0\end{matrix} , G ( x ) = \{ \begin{matrix}1 & x > 0 \\ 0 & otherwise\end{matrix} \qquad ( 7 )$$

Based on the idea of Q learning, the parameters of the deep neural network are updated, and the loss function is defined as follows

$$L ( w ) = {E}_{{z}_{e} , {a}_{e}} [ {( r ( {z}_{e} , {a}_{e} ) + γ {max}_{{a}_{e + 1}} {Q}_{w}^{′} ( {z}_{e + 1} , {a}_{e + 1} , {w}^{′} ) - {Q}_{w} ( {z}_{e} , {a}_{e} ) )}^{2} ] \qquad ( 8 )$$

where Q_{w} is a Q value function of the critic network, represented by the neural network; w is a neural network parameter; zₑ is knowledge representation, i.e., zₑ=g(f(sₑ)) obtained by the granular contrastive network under the current scheduling event. zₑ₊₁ is system state knowledge representation corresponding to the occurrence time (e+1) of a next scheduling event obtained by a data prediction model after the scheduling event e implements an actor aₑ, and γ is an attenuation coefficient of the reward in the reinforcement learning process.

The stability of the network is improved in a mode of soft update, and Q′_{w} represents a target critic network with a parameter w′. A parameter update formula of the critic network is as follows

$${∇}_{w} L ( w ) = ( r ( {z}_{e} , {a}_{e} ) + γ {max}_{{a}_{e + 1}} {Q}_{w}^{′} ( {z}_{e + 1} , {a}_{e + 1} , {w}^{′} ) - {Q}_{w} ( {z}_{e} , {a}_{e} ) ) {∇}_{w} {Q}_{w} ( {z}_{e} , {a}_{e} ) \qquad ( 9 )$$

$$w ← w + α \cdot {∇}_{w} L ( w ) \qquad ( 10 )$$

$${w}^{′} ← τ w + ( 1 - τ ) {w}^{′} \qquad ( 11 )$$

where α is a learning rate of the critic network and τ is a soft update coefficient.
2) The actor part compares the value function evaluation Q_{w}(zₑ, uₑ) of the initial scheduling policy with a set long-term scheduling target Q*, and combines with the state space representation zₑ of the energy system to calculate the dynamic compensation amount Δuₑ of the policy uₑ.

In the calculation process of the compensation value, according to the given Q* and the value function evaluation Q_{w}(zₑ, uₑ) obtained by the critic part, a scheduling target return value ΔQ(zₑ, uₑ)=Q*−Q_{w}(zₑ, uₑ) is calculated; and ΔQ(zₑ, uₑ), the state space representation zₑ under the current event and the value function estimation Q_{w}(zₑ, uₑ) are used as the input and a compensation value Δuₑ is used as the output to establish a nonlinear relationship, i.e.,

$$Δ {u}_{e} = f ( Δ Q ( {z}_{e} , {u}_{e} ) , {z}_{e} , {Q}_{w} ( {z}_{e} , {u}_{e} ) ) \qquad ( 12 )$$

A training set is established based on case samples at the historical scheduling time: the nonlinear relationship is fitted by the data-driven method: and the dynamic compensation amount Δuₑ of the initial scheduling policy uₑ is calculated to obtain a final scheduling solution.

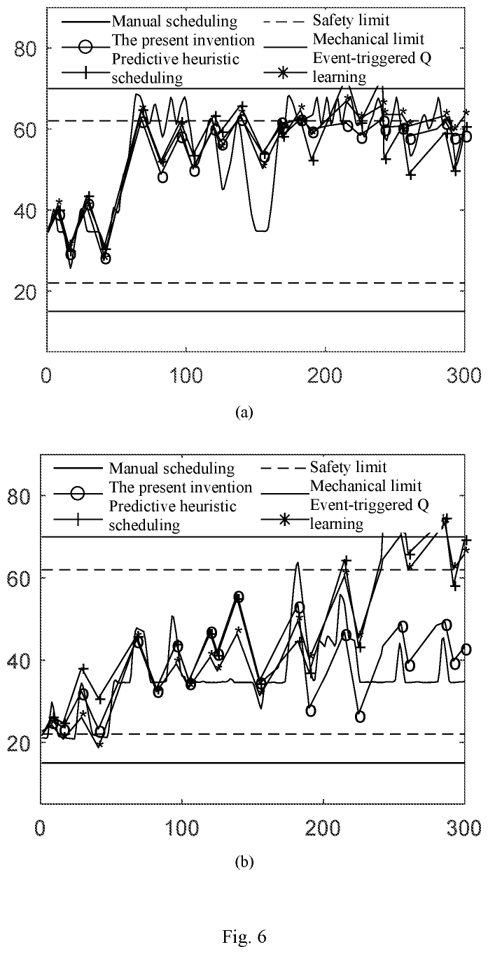

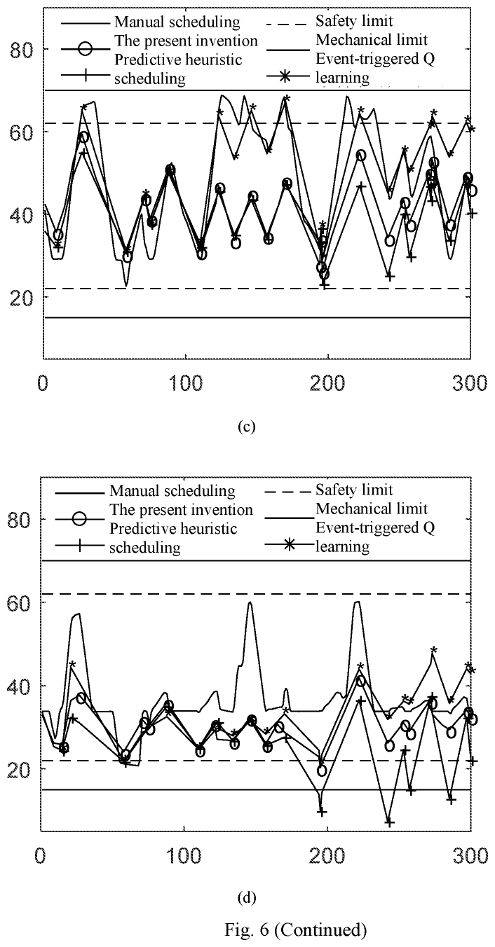

The validity of the proposed method is verified by using continuous 67200 complete data of a converter gas system of a domestic metallurgical enterprise from January to February in 2020 (collected by the SCADA system, at a sampling interval of 1 min), and 600 scheduling samples are selected, wherein 200 samples are used to build the granular contrastive network to generate an initial policy, 300 samples are used for the reinforcement learning process, and the remaining samples are used as a test set. Manual scheduling (method a), prediction-based heuristic scheduling (method b), and event-triggered Q learning method (method c) are used as contrastive experiments, and tank level operation effects under different scheduling scenarios (energy surplus and shortage) within the time of 300 minutes are compared, as shown in FIGS. 5-6. The statistics of various scheduling indicators are shown in Table 1, Table 2 and Table 3.

TABLE 1
Contrast of Statistical Results of Scheduling Indicators (Gas Surplus)

| | | Average | Number of | | |
|---|---|---|---|---|---|
| | | scheduling | Exceeding | | |
| | Number of | time | Safety | Scheduling | Elapsed |
| Algorithm | Scheduling | (min) | Boundaries | Reward | Time (s) |
| Method a | 6 | 58 | 15 | 1.6885 | — |
| Method b | 17 | 18 | 12 | 1.4359 | 45 |
| Method c | 4 | 69 | 7 | 4.1138 | 26 |
| The present | 3 | 104 | 3 | 8.1165 | 37 |
| invention | | | | | |

It can be seen from the statistical results of the indicators in the table above that the number of scheduling in the method b is relatively frequent, resulting in a too low scheduling interval, which is seriously inconsistent with the field situation. Although the number of adjustment in the method a is significantly lower than that of the above two methods, because the method a cannot find an optimal scheduling solution, the number of exceeding the safety boundaries of the tank level is higher than other methods. The method c is easy to fall into a local optimal solution, resulting in that the optimal scheduling solution cannot be found. Compared with the above methods, the present invention obtains the minimum number of adjustment and number of exceeding the safety boundaries, and the scheduling reward within 300 minutes is also significantly higher than other methods.

TABLE 2
Contrast of Statistical Results of Scheduling Indicators (Gas shortage)

| | | Average | Number of | | |
|---|---|---|---|---|---|
| | | scheduling | Exceeding | | |
| | Number of | time | Safety | Scheduling | Elapsed |
| Algorithm | Scheduling | (min) | Boundaries | Reward | Time (s) |
| Method a | 4 | 73 | 29 | 1.4733 | — |
| Method b | 13 | 23 | 12 | 1.4384 | 25 |
| Method c | 5 | 70 | 7 | 10.0187 | 30 |
| The present | 2 | 152 | 6 | 15.8189 | 41 |
| invention | | | | | |

The above table further provides the situation of gas shortage. It can be seen that the number of scheduling in the method b is very frequent, and the scheduling interval is too low, which deviates from the site production demand and cannot be used as a reference for long-term scheduling. Although the method a is obviously better than the above two methods in terms of the number of scheduling, the method a often exceeds the safety boundaries, resulting in no obvious advantage in the actual scheduling reward. The method c is also inferior to the method of the present invention in various statistical indicators. The present invention is obviously better than other methods in terms of the number of adjustment, tank level operation and scheduling reward, and the calculation time can also satisfy the actual needs of the industrial site.

TABLE 3
Contrastive Statistical Results of 50 Scheduling Experiments

| | | Number of | |
|---|---|---|---|
| | | Exceeding | |
| | Number of | Safety | Scheduling |
| Contrastive Indicator | Scheduling | Boundaries | Reward |
| The number of times that the present | 36/5 | 42/0 | 42/0 |
| invention is superior to/inferior to | | | |
| method a | | | |
| The number of times that the present | 50/0 | 48/0 | 48/0 |
| invention is superior to/inferior to | | | |
| method b | | | |
| The number of times that the present | 40/0 | 43/0 | 43/0 |
| invention is superior to/inferior to | | | |
| method c | | | |

The scheduling results of 50 independent experiments are randomly selected from the test samples. 28 independent experiments involve gas surplus and 22 independent experiments involve gas shortage, and the number of times that the present invention is superior to/inferior to other methods is evaluated through the scheduling indicators. It can be seen from Table 3 that the present invention has a superiority rate of 100% in each indicator compared with the method b. Compared with the method a (manual scheduling), the present invention is inferior to the method by 5 adjustments. However, it is observed in the experiments that the gas tank levels with 5 manual adjustments exceed the safety boundaries. The present invention ensures that the tank levels are operated in a safety operation zone by increasing the number of adjustment. In addition, it can be seen from the last two scheduling indicators that the present invention reaches an 84% superiority rate compared with manual scheduling. To sum up, the proposed long-term scheduling method can be applied to different production conditions of the industrial sites to ensure the balanced operation of the byproduct gas system.

1. A long-term scheduling method for an industrial byproduct gas system, comprising the following steps:
(1) feature granulation modeling of energy data dividing data granularity according to the fluctuation tendency characteristics of energy data by an adaptive granulation method; giving a time series X={x₁, x₂, . . . , xₙ}, with first-order and second-order dynamic variables represented as:
$$Δ = \{ {Δ}_{1} , {Δ}_{2} , … , {Δ}_{n - 1} \} , E = \{ {e}_{1} , {e}_{2} , … , {e}_{n - 2} \} \qquad ( 1 )$$
where Δᵢ=xᵢ₊₁−xᵢ and eᵢ=Δᵢ₊₁−Δᵢ; the concavity and convexity, and monotonicity changes of a sequence segment where a data point xᵢ is located are judged by the symbols of Δᵢ×Δᵢ₋₁ and eᵢ×eᵢ₋₁, and time series data are divided at the time when properties are changed; for a time series X={x₁, x₂, . . . , xₚ, xₚ₊₁, . . . , xₙ}, if Δₚ×Δₚ₋₁<0∪eₚ×eₚ₋₁<0, xₚ is used as a segmentation point to divide X into {x₁, x₂, . . . , xₚ} and {xₚ₊₁, xₚ₊₂, . . . , xₙ}; before granularity division is implemented, the energy data is filtered and preprocessed at first; to further realize semantic enhancement of the energy data, a three-dimensional feature vector composed of a time span D_{τ}, a fluctuation amplitude A_{τ} and a tendency linetype L_{τ} is used to describe an information grain G_{τ}, recorded as G_{τ}={D_{τ}, A_{τ}, L_{τ}}, where τ is a granularity time step;
(2) knowledge extraction and policy calculation based on a granular contrastive network establishing a granular contrastive network to obtain knowledge representation related to a scheduling state, and fitting an expert adjustment amount in a historical scheduling sample based on the knowledge representation to calculate an initial scheduling policy;
the input of a granular contrastive network model is granular description of energy occurrence and consumption and storage flow data, i.e., sₑ={G_{τ}⁽¹⁾, G_{τ}⁽²⁾, . . . , G_{τ}⁽ⁿ⁾}, where e represents different scheduling events and n represents the number of input factors; the granular contrastive network model is divided into the following four parts:
1) firstly, data samples are qualitatively divided into different subsets {sₑ₁ⁱ, sₑ₂ⁱ, . . . }, {sₑ₁^{j}, sₑ₂^{j}, . . . }, . . . , {sₑ₁^{m}, sₑ₂^{m}, . . . } according to the expert scheduling data at historical time;
2) an encoder f(⋅) based on a neural network is used to extract a representation vector from granular feature description of the data; a long short-term memory network is adopted to obtain the feature representation of the scheduling state, i.e., hₑ=f(sₑ)=LSTM(sₑ), where hₑ∈ [symbol] ^{d} is the hidden representation of the network;
3) a neural network mapping layer g(⋅) with a single hidden layer is used to map the extracted representation vector to a contrastive loss space, and state knowledge representation zₑ obtained by the neural network mapping layer has better contrastive learning effect than hₑ of a previous layer; MLP is used to obtain final state knowledge representation, i.e., zₑ=g(hₑ)=MLP(hₑ); after contrastive learning, zₑ can reflect the scheduling state of an energy system compared with sₑ, so zₑ is also used for state space representation in an actor-critic architecture;
4) the fully connected output layer is established based on the state knowledge representation zₑ to obtain the initial scheduling policy, i.e., uₑ=Output(zₑ);
for the learning process of the established granular contrastive network, training is conducted from qualitative and quantitative levels respectively:
1) by minimizing a defined loss function, representation vectors {zₑⁱ, zₑ^{j}} of samples {sₑⁱ, sₑ^{j}} qualitatively divided into the same subset by expert scheduling data are close to each other to differentiate representation vectors {zₑⁱ, zₑ^{k}} of different subset samples {sₑⁱ, sₑ^{k}}, so as to distinguish different scheduling conditions as much as possible; the loss function in this process is defined as follows:
$$loss\_func 1 = - {\sum }_{i} log ( \frac{{\sum }_{j = 1}^{p} {e}^{d ( {z}_{e}^{i} , {z}_{e}^{j} )}}{{\sum }_{j = 1}^{p} {e}^{d ( {z}_{e}^{i} , {z}_{e}^{j} )} + {\sum }_{k = 1}^{q} {e}^{d ( {z}_{e}^{i} , {z}_{e}^{k} )}} ) \qquad ( 2 )$$
where p represents the number of samples belonging to the same subset as zₑⁱ; q represents the number of samples of different subsets; and d(⋅) represents a distance between the vectors, which is measured by cosine similarity;
for multi-category situations contained in the expert scheduling data, a multi-step training policy is proposed; in the process of training, firstly, dichotomous contrastive learning is conducted according to a direction of adjustment, and then, input samples with different adjustment amounts are constructed to conduct repeated learning, so that output representation vectors can distinguish multi-category expert knowledge; if the total number of expert experience samples is N and all possible data pairs are used in the training model, the amount of data information used for training reaches (N)(N−1)/2;
2) after the above training process is ended, a multi-level training mechanism is further proposed to realize the quantitative learning and detailed representation of scheduling knowledge;
firstly, a validation set {s₁, s₂, . . . , sₗ} is defined, and the corresponding state knowledge representation {z₁, z₂, . . . zₗ} is calculated according to the network model obtained from the above process; on the basis of the knowledge representation vectors, an output layer is established to fit expert scheduling amount; an error between calculated scheduling amount and real scheduling amount is used to judge whether the current obtained knowledge representation can satisfy actual system conditions; if the error of a sample data set {\tilde{s}₁, \tilde{s}₂, . . . , \tilde{s}ᵣ} is higher than a set threshold θ, i.e.
$$\vert {y}_{e} - Output ( g ( f ( {\tilde{s}}_{e} ) ) ) \vert > θ , e ∈ [ 1 , r ] \qquad ( 3 )$$
where yₑ is the real scheduling amount; it indicates that the current representation space cannot cover the scheduling knowledge contained in the sample set; in this case, the granular contrastive network needs to be further trained to distinguish {\tilde{s}₁, \tilde{s}₂, . . . , \tilde{s}ᵣ} from other samples in the validation set; because characteristics different from the existing representation space need to be learned, mutually exclusive loss functions are defined in this process;
$$loss\_func 2 = - log ( \frac{1}{{\sum }_{i = 1}^{r} {\sum }_{j = 1}^{l - r} {e}^{d ( {\tilde{z}}_{e}^{i} , {z}_{e}^{j} )}} ) \qquad ( 4 )$$
where r is the number of samples that do not meet the conditions, and l is the total number of samples in the validation set; after the above training is ended, it is necessary to judge whether the samples in the validation set can meet the threshold conditions according to the learned network model again, and perform the above process continuously to realize multi-level iterative learning until all the samples meet the set conditions;
after training of the contrastive learning is ended, the input sₑ of the granular contrastive network model is given to obtain the corresponding state knowledge representation zₑ; the fully connected output layer is established based on zₑ; the expert scheduling amount is fitted in a mode of supervised learning; and the initial scheduling policy based on expert knowledge is calculated;
(3) calculation of compensation policy based on the actor-critic architecture for the long-term scheduling performance of the byproduct energy system, proposing an actor-critic architecture to realize dynamic compensation for the initial scheduling policy, wherein the critic part uses the state knowledge representation zₑ as the state of reinforcement learning to establish a deep Q network for calculating the value function evaluation of the scheduling policy; the actor part uses the initial scheduling policy calculated by the granular contrastive network as the initial solution, obtains the compensation amount of the scheduling policy in a mode of data fitting according to a deviation between the critic value of the policy and a target setting value, and iteratively calculates a final scheduling solution;
1) the critic part constructs a critic network to evaluate the scheduling policy; the input of the network is a set of state knowledge representation zₑ and actor aₑ which are spliced through a layer of neural network respectively; on this basis, multiple hidden layers and ReLU activation function layers are constructed to establish a deep neural network; and the output of the network is a value function Q, with a critic network structure;
a scheduling reward is calculated at a moment when each scheduling event occurs, so a value function with the scheduling event as a unit is defined, i.e.,
$$Q = {reward}_{q} + {γreward}_{2} + … + {γ}^{v - 1} {reward}_{v} = {\sum }_{e = 0}^{v - 1} {γ}^{e} {reward}_{e} \qquad ( 5 )$$
where rewardₖ is defined as the reward of the k^{th} scheduling event, which is described by the critic indicator of the scheduling effect of the byproduct gas system, and defined as
$$reward = \frac{\begin{matrix}prof - loss ▯ ( len - {\sum }_{i = 1}^{len} G ( sign ( ( {t\_level}_{i} + \\ θ - HMB ) ( LMB - θ - {t\_level}_{i} ) ) ) )\end{matrix}}{1 + len - {\sum }_{i = 1}^{len} G ( sign ( ( {t\_level}_{i} - LSB ) ( HSB - {t\_level}_{i} ) ) )} \qquad ( 6 )$$
where prof is a fixed profit; loss is a profit lost each time that a tank level reaches mechanical upper and lower limits; the content in parentheses after the loss represents the number of times that the tank level reaches the mechanical upper and lower limits; len is the duration of the scheduling event; θ is a threshold with a smaller value; t_levelᵢ is a tank level value at the i^{th} moment; HMB, LMB, HSB and LSB represent the mechanical upper and lower limits and safety upper and lower limits of the tank level respectively, and sign(▪) and G(▪) functions are respectively shown in formula (7):
$$sign ( x ) = \{ \begin{matrix}1 & x > 0 \\ 0 & x = 0 \\ - 1 & x < 0\end{matrix} , G ( x ) = \{ \begin{matrix}1 & x > 0 \\ 0 & otherwise\end{matrix} \qquad ( 7 )$$
based on the learning idea of the Q network, the parameters of the deep neural network are updated, and the loss function is defined as follows:
$$L ( w ) = {E}_{{z}_{e} , {z}_{e}} [ {( r ( {z}_{e} , {a}_{e} ) + γ {max}_{{a}_{e + 1}} {Q}_{w}^{′} ( {z}_{e + 1} , {a}_{e + 1} , {w}^{′} ) - {Q}_{w} ( {z}_{e} , {a}_{e} ) )}^{2} ] \qquad ( 8 )$$
where Q_{w} is a Q value function of the critic network, represented by the neural network; w is a weight parameter of the current critic network; zₑ is state knowledge representation, i.e., zₑ=g(f(sₑ)), obtained by the granular contrastive network under the current scheduling event; zₑ₊₁ is system state knowledge representation corresponding to the occurrence time (e+1) of a next scheduling event obtained by a data prediction model after the scheduling event e implements an actor aₑ; and γ is an attenuation coefficient of the reward in the reinforcement learning process;
the stability of the network is improved in a mode of soft update, and Q′_{w} represents a target critic network; a parameter update formula of the critic network is as follows:
$${∇}_{w} L ( w ) = ( r ( {z}_{e} , {a}_{e} ) + γ {max}_{{a}_{e + 1}} {Q}_{w}^{′} ( {z}_{e + 1} , {a}_{e + 1} , {w}^{′} ) - {Q}_{w} ( {z}_{e} , {a}_{e} ) ) {∇}_{w} {Q}_{w} ( {z}_{e} , {a}_{e} ) \qquad ( 9 )$$
$$w ← w + α \cdot {∇}_{w} L ( w ) \qquad ( 10 )$$
$${w}^{′} ← τ w + ( 1 - τ ) {w}^{′} \qquad ( 11 )$$
where α is a learning rate of the critic network and τ is a soft update coefficient;
2) the actor part compares the value function evaluation Q_{w}(zₑ, uₑ) of the initial scheduling policy with a set long-term scheduling target Q*, and combines with the state knowledge representation zₑ of the energy system to calculate the dynamic compensation amount Δuₑ of the initial scheduling policy uₑ;
in the calculation process of the compensation value, according to the given Q* and the value function evaluation Q_{w}(zₑ, uₑ) obtained by the critic part, a scheduling target return value ΔQ(zₑ, uₑ)=Q*−Q_{w}(zₑ, uₑ) is calculated; and ΔQ(zₑ, uₑ), the state knowledge representation zₑ under the current scheduling event and the value function estimation Q_{w}(zₑ, uₑ) are used as the input and a compensation value Δuₑ is used as the output to establish a nonlinear relationship, i.e.,
$$Δ {u}_{e} = f ( Δ Q ( {z}_{e} , {u}_{e} ) , {z}_{e} , {Q}_{w} ( {z}_{e} , {u}_{e} ) ) \qquad ( 12 )$$
a training set is established based on case samples at the historical scheduling time; the nonlinear relationship is fitted by the data-driven method; and the dynamic compensation amount Δuₑ of the initial scheduling policy uₑ is calculated to obtain a final scheduling solution.
